(19) United States
(12) Patent Application Publication
(10) Pub. No.: US 2013/0002315 A1
(43) Pub. Date: Jan. 3, 2013

(54) ASYNCHRONOUS CLOCK ADAPTER

(76) Inventor: Philippe Boucard, Le Chesnay (FR)

(21) Appl. No.: 13/539,185

(22) Filed: Jun. 29, 2012

Related U.S. Application Data
(60) Provisional application No. 61/504,135, filed on Jul. 1, 2011.

(51) Int. Cl. H03L 7/00

(52) U.S. Cl. 327/141

(57) ABSTRACT

An asynchronous clock adapter is disclosed that transmits multiple data elements from a buffer in a source clock domain to a data register in a destination clock domain. The buffer can be selected by a pointer register in the destination clock domain and a round trip timing path exists from the pointer register to the data register. Data elements from the buffer can be sent on interleaved cycles of the destination clock such that each data element can have a delay constraint of more than one clock period.

### CROSS-REFERENCE TO RELATED APPLICATIONS

This application claims priority to U.S. Provisional Application No. 61/504,135, filed Jul. 1, 2011, entitled “GALS ASYNCHRONOUS CLOCK ADAPTER,” the entire contents of which are incorporated herein by reference.

### TECHNICAL FIELD

The disclosed invention is in the field of network-on-chip (NoC) for system-on-chip (SoC).

### BACKGROUND

A NoC comprises logic in distant parts of a chip. Controlling skew over long distances makes it impractical to use a synchronous clock tree in distant parts of modern chips. Some conventional solutions approach the problem by trying to send data through long channels in a way that it is reliably sampled by a clock edge at the destination. This is done by driving an inverted clock with the data so that the destination register samples on an edge that should fall within the middle of the data stability. This depends on total skew between all data and clock signals being less than one-half cycle over the full distance. It is very difficult to measure the skew. It depends on the capacitive coupling, which can make a very big difference on whether the bits are all changing the same way or interleaved on each cycle. Controlling for such skew is difficult in place and route and requires chip-specific annotation of signals, which makes it difficult to design a NoC as generated register transfer language (RTL). This is unworkable, except at low clock speeds.

Adapting a data channel between registers with different source and destination clocks is well known in the art as an asynchronous clock adapter. Because an asynchronous clock adapter has no requirements on the relationship of two clocks, it is ideal for a data link between different parts of a chip.

Referring to FIG. 1, clocked elements of an asynchronous clock adapter 100 each exist in either a source clock domain or destination clock domain. Source and destination refer to the directionality of data flow. In particular, a buffer 102 (known as a bisynchronous first in first out (FIFO) or circular buffer) in the source domain is connected through a multiplexer (mux) 104 to a data register 106 in the destination clock domain. A write control unit 108 produces a Gray coded write count (WrCnt), registered in the source clock domain. The write control unit 108 is coupled to a stabilization register (S) unit 110 in the destination clock domain with at least two serial registers. The write count is connected to a read control unit 114. The read control unit 114 produces a Gray coded read count (RdCnt), registered in the destination domain. It is connected to a stabilization (S) register unit 116 in the source clock domain with at least two serial registers. The read count is connected to the write control unit 108.

From the write and read count values, the read control unit 114 produces a read pointer (RdPtr), which is registered in the destination clock domain. The read pointer controls the mux 104 to select the next data element to read from the buffer 102. The timing path from the RdPtr register, through the mux 104, and to the data register 106 in the destination clock domain is typically a critical path. It is slow because it twice traverses the distance between the source and destination ends of the asynchronous clock adapter 100. The timing path significantly limits the clock speed of the destination clock domain.

### SUMMARY

The disclosed embodiments include an asynchronous clock adapter that does not limit the clock speed of a destination clock domain when wire delay increases. A number of data channels are connected between source and destination clock domains. Successive data elements from a buffer (e.g., a FIFO buffer) can be sent on the data channels in a rotating order on successive cycles of a destination clock. With multiple data elements (e.g., data words), simultaneously being transmitted on data channels, each word transmission can take multiple cycles. By transmitting the elements in successive clock cycles, the elements can be captured in successive clock cycles, thus keeping the destination link fully utilized at a high clock speed.

The details of the disclosed implementations are set forth in the accompanying drawings and the description below. Other features, objects, and advantages will be apparent from the description and drawings, and from the claims.

### DESCRIPTION OF DRAWINGS

FIG. 1 illustrates the logic of an example asynchronous clock domain adapter.

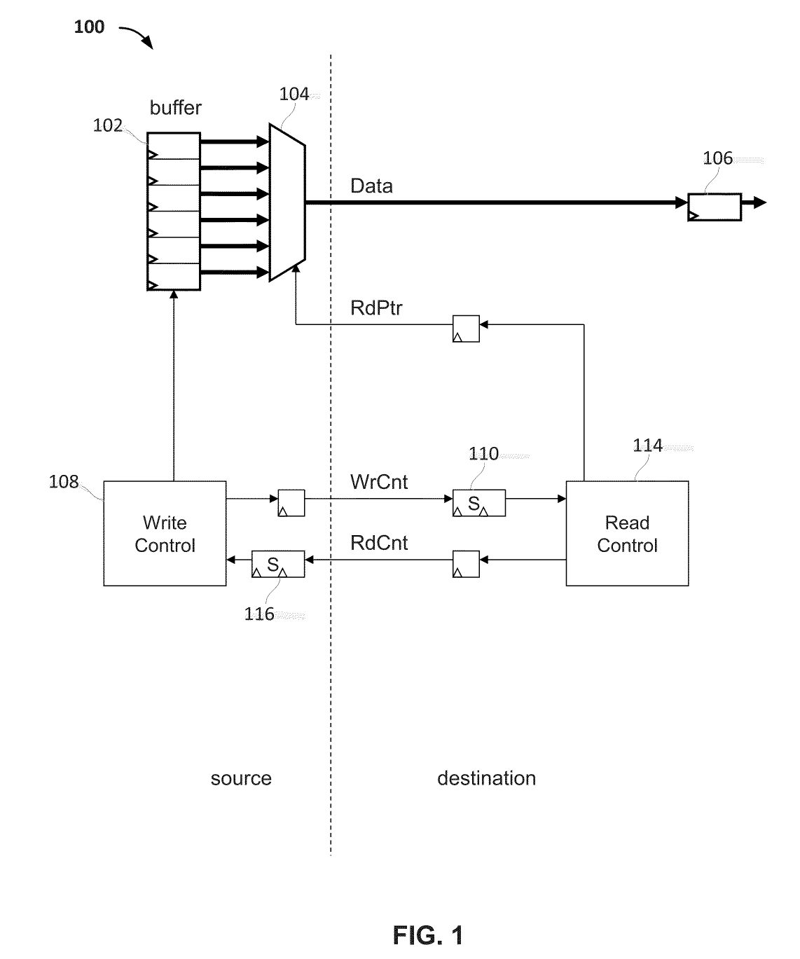

FIG. 2 illustrates an example embodiment of an asynchronous clock domain adapter with two data channels.

FIG. 3 is a flow diagram of an example method performed by the embodiment of FIG. 2.

The same reference symbol used in various drawings indicates like elements.

### DETAILED DESCRIPTION

The disclosed asynchronous clock adapter uses parallelism to allow a lower clock speed for the path from read pointer to destination register. Multiple data elements (e.g., data words) from a buffer are sent simultaneously in parallel on separate data channels. In one embodiment, multiple read pointers each point to a data element in the buffer. In another embodiment, a single read pointer can be used to select a block of several data elements. In both embodiments, the timing path from each read pointer to the destination register can be a multi-cycle path in the destination clock domain.

In one embodiment, each channel can carry any data element from the buffer. This gives more flexibility to the read pointer, and is most efficient when the number of buffered data elements is not an integer multiple of the number of data channels. In another embodiment, only some data elements of the buffer are connected to each data channel. This latter embodiment has the benefit of reducing the number of inputs to a mux that selects between buffered data elements. Fewer mux inputs reduce the required silicon area and reduces clock delay.

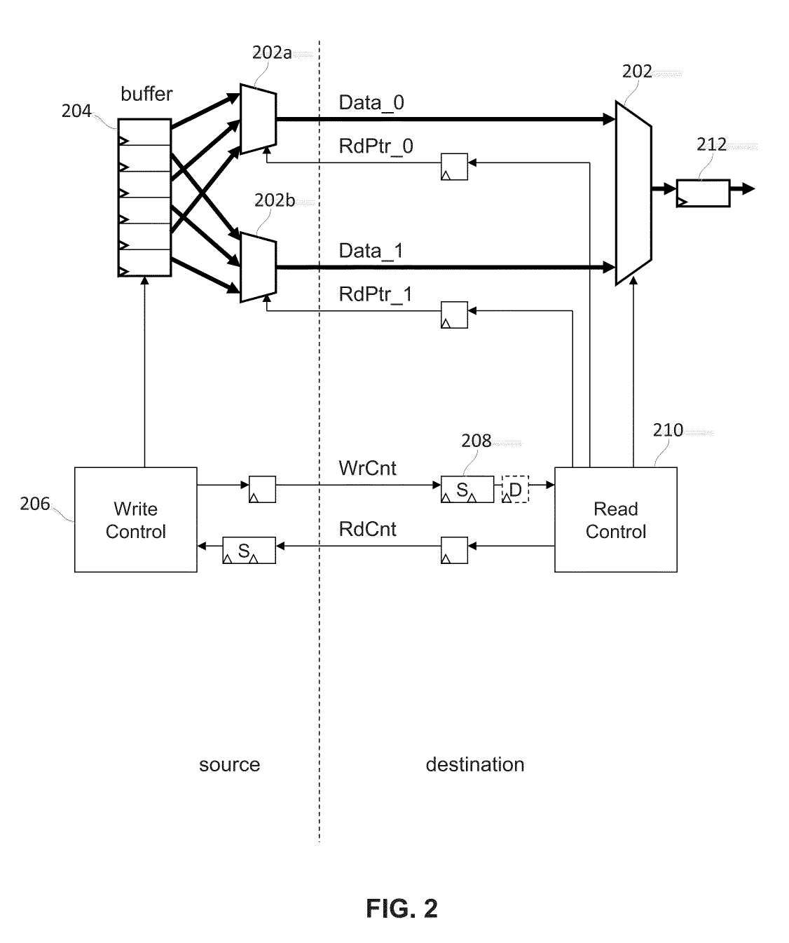

The example embodiment shown in FIG. 2 has c data channels: (e.g., data channels 0 and 1). Each data channel includes a data path: (e.g., Data_0 and Data_1) and a corresponding read pointer (e.g., RdPtr_0 and RdPtr_1), respectively. Each data channel is connected to the output of a corresponding mux 202a, 202b, each of which selects between n non-overlapping data elements (e.g., three data elements) at interleaved positions in a c times n element buffer 204 (e.g., six element buffer).

A write control module 206 controls the writing of sequentially received source data elements into data elements of the buffer 204. The write control 206 module receives a Gray coded read count value, RdCnt. The write control module 206 synchronizes RdCnt through at least two sequential register stages, clocked by the source clock, to settle out metastability of the flip-flops of the registers. The write control module 206 sends a coded write count value, WrCnt, which is synchronized in registers 208 clocked by the destination clock. A read control unit 210 receives WrCnt and sends RdCnt in correspondence with the write control unit 206. The read control unit 210 generates the read pointers, RdPtr_0 and RdPft_1, to select the next buffer data element to transfer. The read control unit 210 also controls the mux 202 that selects between data channels.

In the example embodiment of FIG. 2, RdPtr_0 and RdPtr_1 are incremented, modulo 3, in alternate cycles. After two cycles (minus clock to Q and setup delay), the data from the data channel will be captured by the destination register 212. The mux 202 connected directly to the destination register 212 alternates its selected input on every clock cycle when valid data is present in the buffer 204 (write count is greater than read count). When no valid data is present (e.g., when the read count is equal to the write count) then the mux 202 input selection value and both read pointers remain unchanged. This embodiment allows the source and destination logic to be placed a distance apart on the chip such that the propagation time on the interconnecting wires is about two times the destination clock period.

In another embodiment, the inputs to mux 202a, 202b, are connected to sequential (non-interleaved) data elements of the buffer 204. In such a configuration, the write control module 206 would assign incoming data elements to non-sequential locations within the buffer 204.

In another embodiment, mux 202a, 202b, have an input for each element of buffer 204. In such a configuration, data elements of the buffer 204 can be transferred in any order. In this configuration, the buffer need not have a number of data elements that is equal to a multiple of the number of data channels.

Logic synthesis of the asynchronous clock adapter can use a max_delay constraint between each read pointer and the destination register 212 equal to the clock period times the number of channels. Likewise, a max_delay constraint between the buffer registers and the destination register can be set equal to the clock period times the number of channels.

In an embodiment with four channels, with a max_delay constraint of four times the destination clock period, it is possible for the delay of data registered in the buffer 204 to become valid at the destination register 212 only after four clock periods of duration. Since the WrCnt value is only synchronized through two registers, it is possible that the Rd_Ptr would cause the destination register 212 to receive the previous value of the pointer buffer 204. To avoid this possibility, an embodiment with more than 3 channels can include an additional clock of delay, typically in the form of an additional write count register, for each channel beyond three. Such an embodiment can include the delay register(s) in the location shown as register D in FIG. 2.

The Gray coded RdCount can still be transferred in a single clock cycle of the source clock and the WrCount can still be transferred in a single clock cycle of the destination clock in order to avoid the possibility of multiple increments of the Gray coded counter occurring before the counter value is registered in its receiving synchronization register. However, the Gray coded counters can have relatively small buses, which can be implemented with wide wires and strong drivers.

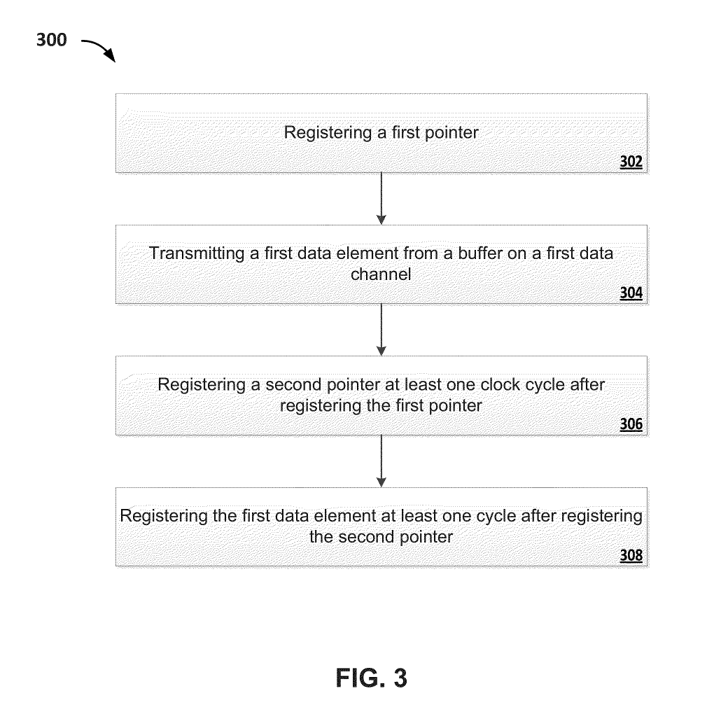

FIG. 3 is a flow diagram of an example process 300 performed by the embodiment described in reference to FIG. 2.

In some implementations, process 300 includes registering a first pointer (302); transmitting a first data element from a buffer on a first data channel (304); registering a second pointer at least one clock cycle after registering the first pointer (306); and registering the first data element at least one cycle after registering the second pointer (308).

In some implementations, process 300 can also include the steps of accepting a write count; delaying the registering of the first pointer until the write count exceeds a read count; and delaying the acceptance of the write count for at least one cycle.

What is claimed is:

1. An asynchronous clock domain adapter comprising:
a number of data channels; and
a buffer including a number of data elements coupled to the data channels, the buffer, data channels and data elements configured such that different data channels can transmit data elements from data elements of the buffer on successive cycles of a destination clock.

2. The asynchronous clock domain adapter of claim 1 further comprising a number of read pointers equal to the number of data channels.

3. The asynchronous clock domain adapter of claim 1 further comprising at least one write count delay register.

4. The asynchronous clock domain adapter of claim 1 wherein the data channels are connected to different data elements of the buffer.

5. The asynchronous clock domain adapter of claim 4 wherein the data channels are connected to interleaved data elements of the buffer.

6. A method of transferring data between clock domains comprising:
registering a first pointer;
transmitting a first data element from a buffer on a first data channel;
registering a second pointer at least one clock cycle after registering the first pointer; and
registering the first data element at least one cycle after registering the second pointer.

7. The method of claim 6 further comprising:
accepting a write count;
delaying the registering of the first pointer until the write count exceeds a read count; and
delaying the acceptance of the write count for at least one cycle.

8. The method of claim 6 wherein the second pointer indicates a next data element following the first data element in a repeating sequence.
